(19) United States
(12) Patent Application Publication
(10) Pub. No.: US 2016/0149032 A1
(43) Pub. Date: May 26, 2016

(54) Power Transistor with Field-Electrode

(71) Applicant: Infineon Technologies Dresden GmbH, Dresden (DE)

(72) Inventors: Martin Bartels, Dresden (DE); Rolf Weis, Dresden (DE)

(21) Appl. No.: 14/943,524

(22) Filed: Nov. 17, 2015

(30) Foreign Application Priority Data
Nov. 25, 2014 (DE) 102014117242.6

(51) Int. Cl. H01L 29/78; H01L 29/08; H01L 29/66; H01L 29/10

(52) U.S. Cl. CPC H01L 29/7816; H01L 29/1095; H01L 29/086; H01L 29/0878; H01L 29/66681

(57) ABSTRACT

A semiconductor device includes at least two transistor cells. Each of these at least two transistor cells includes: a drain region, a drift region, and a body region in a semiconductor fin of a semiconductor body; a source region adjoining the body region; a gate electrode adjacent the body region and dielectrically insulated from the body region by a gate dielectric; and a field electrode dielectrically insulated from the drift region by a field electrode dielectric, and connected to the source region. The field electrode dielectric is arranged in a first trench between the semiconductor fin and the field electrode. The at least two transistor cells include a first transistor cell, and a second transistor cell. The semiconductor fin of the first transistor cell is separated from the semiconductor fin of the second transistor cell by a second trench different from the first trench.

### PRIORITY CLAIM

This application claims priority to German Patent Application No. 10 2014 117 242.6 filed on 25 Nov. 2014, the content of said application incorporated herein by reference in its entirety.

### TECHNICAL FIELD

Embodiments of the present invention relate to a power transistor, in particular a power field-effect transistor.

### BACKGROUND

Power transistors, in particular power field-effect transistors, such as power MOSFETs (Metal Oxide Field-Effect Transistors) or power IGBTs (Insulated Gate Bipolar Transistors) are widely used as electronic switches in drive applications, such as motor drive applications, or power conversion applications, such as AC/DC converters, DC/AC converters, or DC/DC converters.

There is a need to provide a power transistor that is capable of blocking a high voltage and that has a low specific on-resistance (the on-resistance multiplied with the semiconductor area (chip size) of the power transistor). In addition, it is very useful to use a minimum sized transistor for simple analog or logic circuitry, especially if manufactured on the same wafer.

### SUMMARY

One embodiment relates to a power transistor. The power transistor includes at least two transistor cells, each including a drain region, a drift region, and a body region in a semiconductor fin of a semiconductor body, a source region adjoining the body region, a gate electrode adjacent the body region and dielectrically insulated from the body region by a gate dielectric, and a field electrode dielectrically insulated from the drift region by a field electrode dielectric and connected to the source region. The field electrode dielectric is arranged in a first trench between the semiconductor fin and the field electrode. The at least two transistor cells comprise a first transistor cell, and a second transistor cell. The semiconductor fin of the first transistor cell is separated from the semiconductor fin of the second transistor cell by a second trench different from the first trench.

Another embodiment relates to a method. The method includes forming a gate electrode, a gate electrode dielectric and a field electrode dielectric in each of a first trench adjacent a first semiconductor fin, and a second trench adjacent a second semiconductor fin, forming an insulation layer in a third trench between the first and the second semiconductor fin, forming a first field electrode spaced apart from the insulation layer and the first semiconductor fin and adjacent the field electrode dielectric formed in the first trench, and forming a second field electrode spaced apart from the insulation layer and the second semiconductor fin and adjacent the field electrode dielectric formed in the second trench.

### BRIEF DESCRIPTION OF THE DRAWINGS

Examples are explained with reference to the drawings. The drawings serve to illustrate the basic principle, so that only aspects necessary for understanding the basic principle are illustrated. The drawings are not to scale. In the drawings the same reference characters denote like features.

FIG. 1 illustrates a vertical cross sectional view of a power transistor, according to one embodiment.

FIG. 2 illustrates a top view of the power transistor shown in FIG. 1, according to one embodiment.

FIG. 3 illustrates a vertical cross sectional view of a power transistor, according to one embodiment.

FIG. 4 illustrates a top view of the power transistor shown in FIG. 3, according to one embodiment;

FIG. 5 illustrates a vertical cross sectional view of a power transistor, according to another embodiment.

FIG. 6 shows a vertical cross sectional view in a section plane perpendicular to the section planes shown in FIGS. 1, 3 and 5 of one of the power transistors shown in FIGS. 1, 3 and 5, according to one embodiment.

FIG. 7 illustrates a top view of one of the power transistor shown in FIGS. 1, 3 and 5, according to one embodiment.

FIG. 8 illustrates a vertical cross sectional view of the power transistor shown in FIG. 7, according to one embodiment.

FIG. 9 shows a vertical cross sectional view in a section plane perpendicular to the section planes shown in FIGS. 1, 3 and 5 of one of the power transistors shown in FIGS. 1, 3 and 5, according to one embodiment.

FIGS. 10A-10H illustrate a method for producing a power transistor according to one embodiment, according to one embodiment.

### DETAILED DESCRIPTION

In the following detailed description, reference is made to the accompanying drawings. The drawings form a part of the description and by way of illustration show specific embodiments in which the invention may be practised. It is to be understood that the features of the various embodiments described herein may be combined with each other, unless specifically noted otherwise.

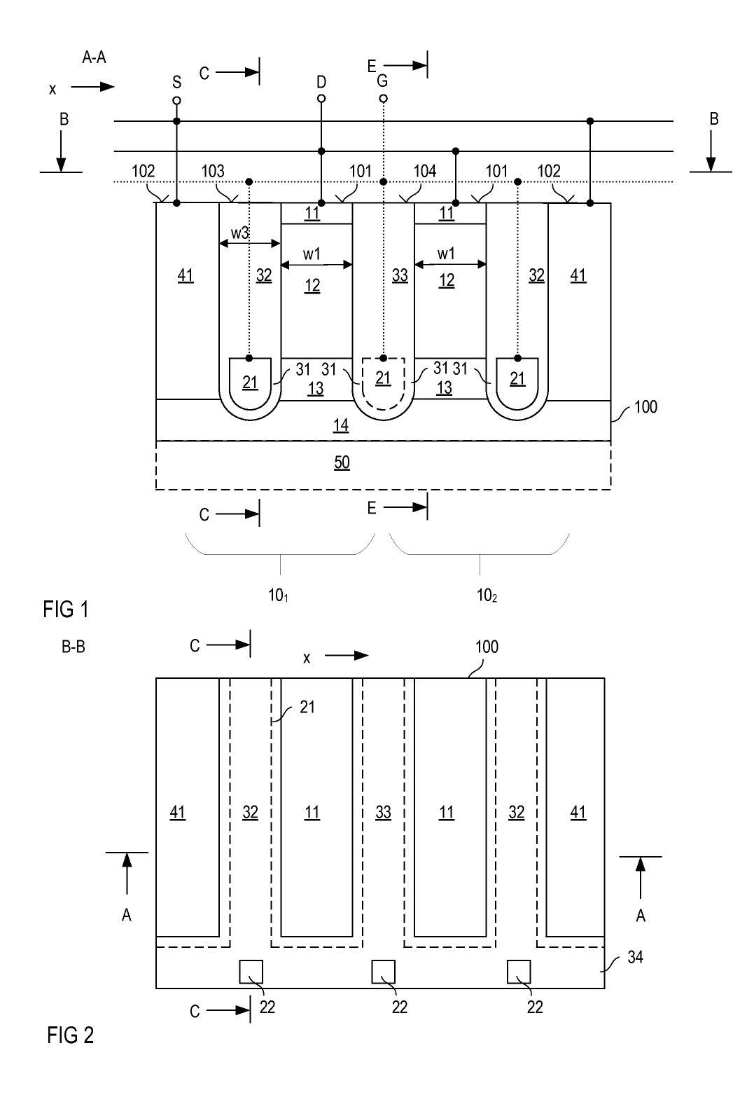

FIGS. 1 and 2 illustrate a power transistor according to one embodiment. FIG. 1 shows a vertical cross sectional view of a portion of a semiconductor body 100 in which active device regions of the power transistor are integrated, and FIG. 2 shows a top view of the semiconductor body 100. Referring to FIGS. 1 and 2, the power transistor includes a plurality of substantially identical transistor cells. “Substantially identical” means that the individual transistor cells have identical device features, but may be different in terms of their orientation in the semiconductor body 100. In particular, the power transistor includes at least two transistor cells 10₁, 10₂ which, in the following, will be referred to as first and second transistor cells, respectively. In the following, when reference is made to an arbitrary one of the transistor cells or to the plurality of transistor cells, and when no differentiation between individual transistor cells is necessary, reference character 10 will be used to denote one or more of the plurality of transistor cells.

Referring to FIG. 1, each transistor cell 10 includes a drain region 11, a drift region 12, and body region 13 in a semiconductor fin of the semiconductor body 100. Further, a source region 14 adjoins the body region 13 of each transistor cell 10. In the present embodiment, the individual transistor cells 10 have the source region 14 in common. That is, the source region 14 is a continuous semiconductor region which adjoins the body regions 13 of the individual transistor cells 10, wherein the body regions 13 (as well as the drain regions 11 and the drift regions 12) of the individual transistor cells 10 are separate semiconductor regions. In another embodiment, the source and/or the body region of each individual transistor may be structural separated but electrically connected.

Referring to FIG. 1, each transistor cell 10 further includes a gate electrode 21 adjacent the body region 13 and dielectrically insulated from the body region 13 by a gate dielectric 31. Further, a field electrode 41 is dielectrically insulated from the drift region 12 by a field electrode dielectric 32 and is electrically connected to the source region 14.

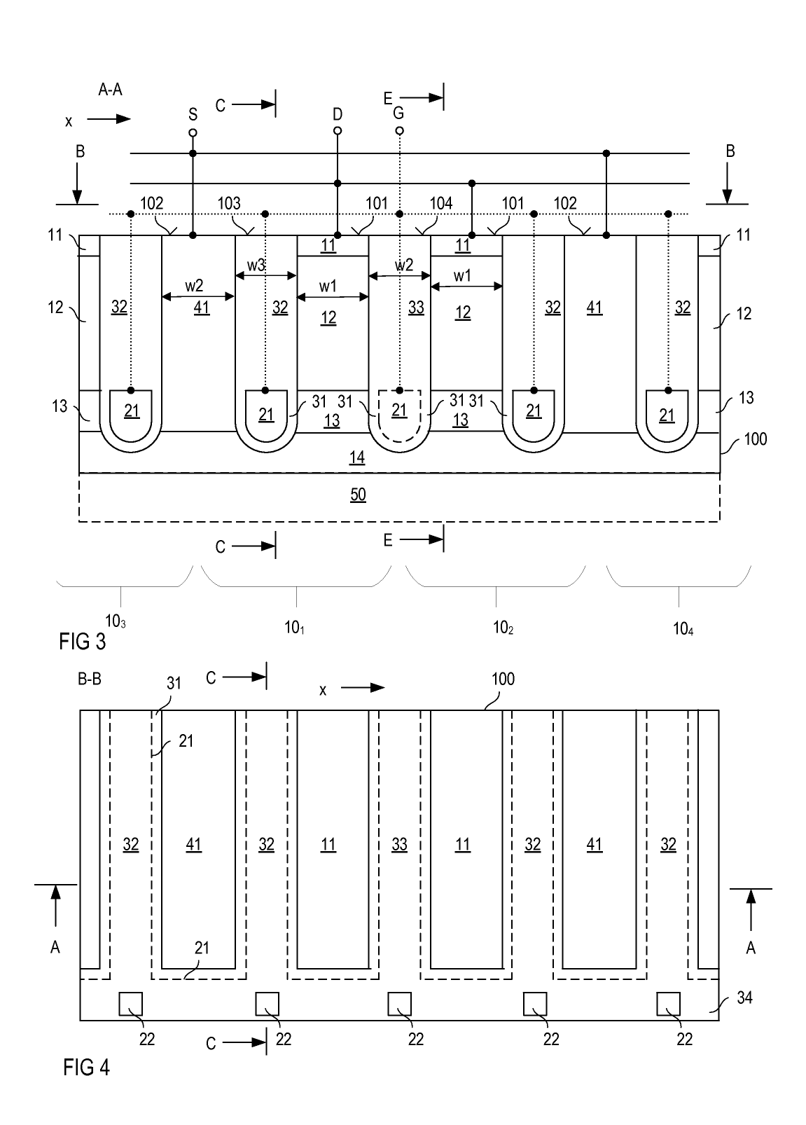

FIGS. 3 and 4 illustrate one embodiment of a power transistor which includes at least three transistor cells. Besides the first and second transistor cells 10₁, 10₂ explained with reference to FIGS. 1 and 2, the power transistor shown in FIGS. 3 and 4 includes a third transistor cells 10₃ adjacent to the first transistor cell 10₁. In this embodiment, two neighboring transistor cells share one field electrode 41. That is, one and the same field electrode 41 is dielectrically insulated from the drift region of one transistor cell by one field electrode dielectric 32, and is dielectrically insulated from the drift region 12 of another transistor cell by another field electrode dielectric 32. For example, the first transistor cell 10₁ and the third transistor cell 10₃ share one field electrode 41, so that the field electrode 41 of the first and third transistor cells 10₁, 10₃ is dielectrically insulated from the drift region 12 of the first transistor cell 10₁ by a field electrode dielectric 32 of the first transistor cell 10₁, and is dielectrically insulated from the drift region 12 of the neighboring third transistor cell 10₃ by the field electrode dielectric 32 of the third transistor cell 10₃. Equivalently, the second transistor cell 10₂ and a fourth transistor cell adjacent the second transistor cell 10₂ share one field electrode, so that the field electrode 41 of the second and fourth transistor cells 10₂, 10₄ is dielectrically insulated from the drift region 12 of the second transistor cell 10₂ by a field electrode dielectric 32 of the second transistor cell 10₂, and is dielectrically insulated from the drift region 12 of the neighboring fourth transistor cell 10₄ by the field electrode dielectric 32 of the fourth transistor cell 10₃.

In the embodiments shown in FIGS. 1 and 3, the gate electrode 21, the gate dielectric 31, and the field electrode dielectric 32 of each transistor cell 10 (wherein in FIG. 3 reference character 10 represents transistors cells 10₁-10₄) are arranged in a first trench adjacent the drain region 11, the drift region 12, and the body region 13 of the corresponding transistor cell 10. The field electrode may terminate the power transistor in lateral direction, or, as illustrated in FIG. 3, may be located between the first trenches of two transistor cells which share the field electrode 41.

In the embodiment shown in FIG. 3, the field electrode 41 shared by the first transistor cell 10₁ and the third transistor cell 10₃ is arranged between the first trench which accommodates the gate electrode 21, the gate dielectric 31 and the field electrode dielectric 32 of the first transistor cell 10₁ and the first trench which accommodates the gate electrode 21, the gate dielectric 31 and the field electrode dielectric 32 of the third transistor cell 10₃. Equivalently, the field electrode 41 shared by the second transistor cell 10₂ and the fourth transistor cell 10₄ is arranged between the first trench which accommodates the gate electrode 21, the gate dielectric 31 and the field electrode dielectric 32 of the second transistor cell 10₂ and the first trench which accommodates the gate electrode 21, the gate dielectric 31 and the field electrode dielectric 32 of the fourth transistor cell 10₄.

The semiconductor fin that includes the drain region 11, the drift region 12 and the body region 13 of the first transistor cell 10₁ is separated from the semiconductor fin which insulates the drain region 11, the drift region 12, and the body region 13 of the second transistor cell 10₂ by a second trench which includes an electrically insulating, or dielectrically insulating material 33.

In the embodiments shown in FIGS. 1 and 3, the first transistor cell 10₁ and the second transistor cell 10₂ are substantially axially symmetric, with the symmetry axis going through the second trench with the insulating material 33. In the embodiment shown in FIG. 3, the first transistor cell 10₁ and the third transistor cell 10₃, as well as the second transistor cell 10₂ and the fourth transistor cell 10₄ are substantially axially symmetric, with the symmetry axis going through the common field electrode 41.

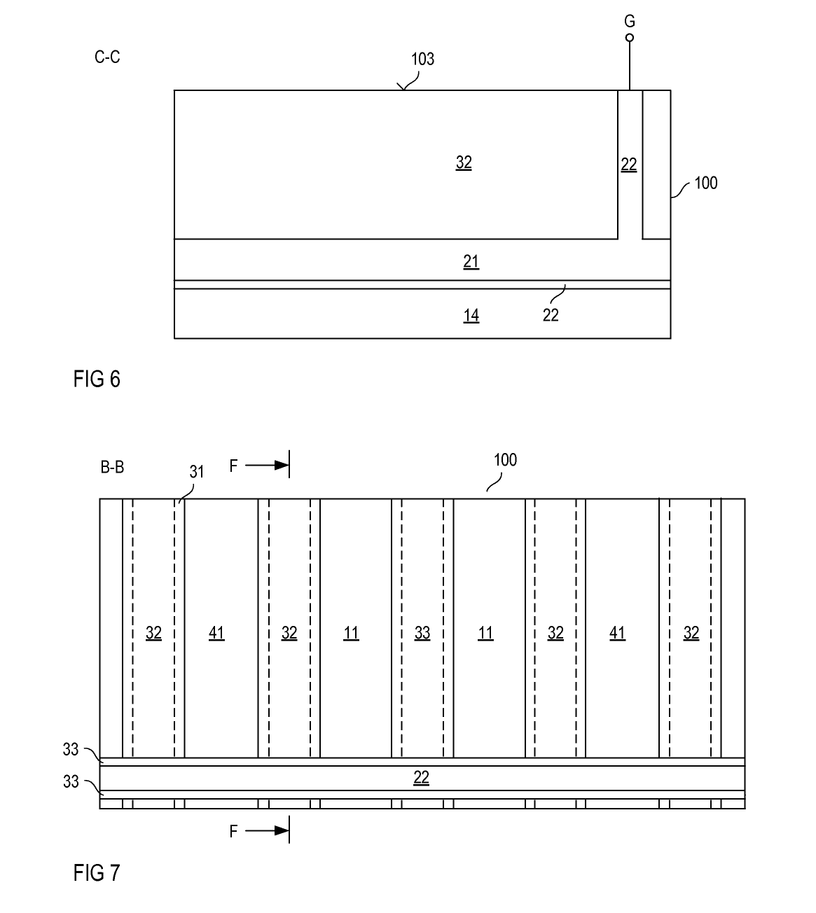

Referring to FIGS. 1 and 3, the individual transistor cells 10 are connected in parallel by having their drain regions 11 electrically connected to a drain node D, by having their gate electrodes 21 electrically connected through a gate node G, and by having the source region 14 connected to a source node S. An electrical connection between the drain regions 11 and the drain node D is only schematically illustrated in FIG. 1. This electrical connection can be implemented using conventional wiring arrangements implemented on top of a semiconductor body. Equivalently, an electrical connection between the field electrodes 41 and the source node S are only schematically illustrated in FIGS. 1 and 3. Electrical connections between the gate electrode 21 and the gate node G are illustrated in dotted lines in FIGS. 1 and 3. In the embodiments shown in FIGS. 1 and 3, these gate electrodes 21 are buried below the field electrode dielectric 32 in the first trenches. One way of how these gate electrodes 21 are connected to the gate node G is explained with reference to FIG. 6 herein below.

In FIGS. 1 and 3, reference character 101 denotes surfaces of the semiconductor fins of the individual transistor cells 10. Reference character 102 denotes surfaces of the field electrodes 41, reference character 103 denotes surfaces of the field electrode dielectrics 32, and reference character 104 denotes surfaces of the insulating material 33 in the second trenches. According to one embodiment, these surfaces 101, 102, 103, and 104 are substantially in the same horizontal plane. The drain regions 11 may be contacted at the surfaces 101 in order to connect the drain regions 11 to the drain node D, and the field electrodes 41 may be contacted in the surfaces 102 in order to connect the field electrodes 41 to the common source node S.

Referring to FIGS. 1 and 3, the semiconductor fin of each transistor cell 10 has a first width w1. This first width w1 corresponds to the distance between the first trench adjoining the semiconductor fin and accommodating the field electrode dielectric 32 and the second trench adjoining the semiconductor fin and accommodating the insulating material 33. According to one embodiment, the first width w1 is selected from a range of between 10 nm (nanometers) and 100 nm. According to one embodiment, the semiconductor fins of the individual transistor cells 10 have substantially the same first width w1. According to another embodiment, the first widths w1 of the individual semiconductor fins are mutually different.

A width w2 of the field electrode 41 may be in the same range explained with reference to the first width w1 above when the field electrode 41 is shared by two transistor cells, as illustrated in FIG. 3. When the field electrode 41 terminates a cell region with several transistor cells it may be wider. A third width w3 of the field electrode dielectric 32 is, for example, between 30 nm and 300 nm As, referring to FIGS. 1 and 3, the field electrode dielectric 33 fills the trench above the gate electrode 21 and the gate dielectric 31 the width w3 of the field electrode dielectric 33 is greater than a thickness of the gate dielectric 31.

The first width w1 is the dimension of the semiconductor fin in a first horizontal direction x of the semiconductor body 100. Referring to FIGS. 2 and 4, which show top views of the semiconductor body 100, the semiconductor fin with the drain region 11, the drift region 12 and the body region 13 (whereas FIGS. 2 and 4 only show the drain region 11) has a length in a direction perpendicular to the first horizontal direction x. In FIGS. 2 and 4, the dotted lines show the position of the gate electrodes in the first trenches below the field electrode dielectric 32. According to one embodiment, the length of the semiconductor fin is much longer than the first width w1. According to one embodiment, a ratio between the length and the width w1 is at least 2:1, at least 100:1, at least 1000:1, or at least 10000:1. The same applies to a ratio between a length of the field electrode 41 and the corresponding width w2, and a length of the field electrode dielectric 32 and the corresponding width w3, respectively.

The power transistor shown in FIGS. 1-4 is a FET (Field-Effect Transistor) and, more specifically, a MOSFET (Metal Oxide Field-Effect Transistor) or an IGBT (Insulated Gate Bipolar Transistor). It should be noted that the term MOSFET as used herein denotes any type of field-effect transistor with an insulated gate electrode (often referred to as IGFET) independent of whether the gate electrode includes a metal or another type of electrically conducting material, and independent of whether the gate dielectric includes an oxide or another type of dielectrically insulating material. The drain regions 11, drift region 12, body regions 13, and the source region 14 of the individual transistor cells 10 may include a conventional monocrystalline semiconductor material such as, for example, silicon (Si), germanium (Ge), silicon carbide (SiC), gallium nitride (GaN), gallium arsenide (GaAs), or the like. The gate electrodes 21 may include a metal, TiN, carbon or a highly doped polycrystalline semiconductor material, such as polysilicon or amorphous silicon. The gate dielectrics 31 may include an oxide such as, for example, silicon dioxide (SiO₂), a nitride such as, for example, silicon nitride (Si3N4), an oxinitride or the like. Like the gate electrodes 21, the field electrodes 41 may include a metal, TiN, carbon or a highly doped polycrystalline semiconductor material. Like the gate dielectrics 31, the field electrode dielectrics 32 may include an oxide or a nitride or an oxinitride. The same applies to the insulating material 33.

The power transistor can be implemented as an n-type transistor, or as a p-type transistor. In the first case, the source region 14 and the drift region 12 of each transistor cell 10 is n-doped. In the second case, the source regions 14 and the drift region 12 of each transistor cell 10 is p-doped. Further, the transistor can be implemented as an enhancement (normally-off) transistor, or as a depletion (normally-on) transistor. In the first case, the body regions 13, have a doping type complementary to the doping type of the source region 14, and the drift region 12. In the second case, the body region 13 has a doping type corresponding to the doping type of the source 14 and the drift region 12. Further, the transistor can be implemented as a MOSFET or as an IGBT. In a MOSFET, the drain region has the same doping type as the source region. An IGBT (Insulated Gate Bipolar Transistor) is different from a MOSFET in that the drain region 11 (which is also referred to as collector region in an IGBT) has a doping type complementary to the doping type of the source and drift regions 14, 12.

The doping concentration of the drain regions 11 is, for example, between 1 E19 cm⁻³ and 1 E21 cm⁻³, the doping concentration of the drift region 12 is, for example, between 1 E14 cm⁻³ and 1 E18 cm⁻³, the doping concentration of the body region 13 is, for example, between 1 E14 cm⁻³ and 1 E18 cm⁻³, and the doping concentration of the source region 14 is, for example, between 1 E17 cm⁻³ and 1 E21 cm⁻³.

Referring to FIGS. 1 and 3, the source region 14 is a buried semiconductor region (semiconductor layer), which is distant to the surfaces 101 of the individual semiconductor fins. According to one embodiment (illustrated in dashed lines in FIGS. 1 and 3), the source region 14 adjoins a carrier 50 which may provide for a mechanical stability of the power transistor. According to one embodiment, the carrier 50 is a semiconductor substrate. This semiconductor substrate may have a doping type complementary to the doping type of the source region 14. According to another embodiment, a carrier 50 includes a semiconductor substrate and an insulation layer on the substrate. In this embodiment, the source region 14 may adjoin the insulation layer of the carrier 50.

The power transistor shown in FIG. 1 can be operated like a conventional field-effect transistor, that is, like a conventional MOSFET or conventional IGBT. The power transistor can be switched on or switched off by applying a suitable drive potential to the individual gate electrodes 21 via the gate node G. The power transistor is switched on (is in an on-state) when the drive potential applied to the gate electrodes 21 is such that there is a conducting channel in the body regions 13 between the source region 14 and the drift regions 12. When the power transistor is implemented as an enhancement transistor, there is a conducting channel in the body region 13 of each transistor cell when the corresponding gate electrode 21 is biased such that there is an inversion channel in the body region 13 along the gate electrode dielectric 31. For example, in an n-type enhancement transistor, the drive potential to be applied to the gate electrode 21 in order to switch on the transistor is an electrical potential which is positive relative to the electrical potential at the source node S. In a depletion transistor there is a conducting channel in the body region 13 of each transistor cell 10 when the gate electrode 21 is biased such that the gate electrode 21 does not cause the body region 13 to be depleted. For example, in a depletion transistor, the electrical potential at the gate electrode 21 may correspond to the electrical potential at the source node S in order to switch on the transistor.

When the power transistor is in the off-state and a voltage is applied between the drain and source nodes D, S, a depletion region (space-charge region) may expand in the drift region 12 beginning at the body region 13. For example, in an n-type transistor, a depletion region expands in the drift region 12 when a positive voltage is applied between the drain and source notes D, S, and when the transistor is in the off-state. A depletion region expanding the drift region 12 is associated with ionized dopant atoms in the drift region 12. In the power transistor shown in FIG. 1, a part of these ionized dopant atoms in the drift region 12 finds corresponding counter charges in the field electrode 41. This effect is known from field-effect transistors having a field electrode (field plate) adjacent a drift region. The field electrode, such as the field electrode 41 shown in FIG. 1, allows the power transistor to be implemented with a doping concentration of the drift region 12 higher than the doping concentration of a comparable power transistor without field electrode, without reducing the voltage blocking capability. The higher doping concentration of the drift region 11, however, provides for a lower on-resistance of the power transistor.

In the power transistor shown in FIGS. 1 and 3, the field electrode 21 not only acts as a field electrode, but also is used to electrically connect the buried source region 14 to the source node S. By virtue of these two functionalities of the field electrode 41, the power transistor can be implemented in a space-saving way. What also leads to a space-saving implementation is the fact that, in an arrangement with three or more device cells shown in FIGS. 3 and 4, one field electrode 41 is shared by two neighboring transistor cells, such as the first and third transistor cells 10₁, 10₃ shown in FIG. 3.

In the embodiments shown in FIGS. 1 and 3, the gate electrode 21 of each transistor cell 10 is arranged in the first trench, adjacent the body region 13, and dielectrically insulated from the body region 13 by the gate dielectric 31. According to another embodiment (illustrated in dashed lines in FIGS. 1 and 3) the gate electrode 21 of one transistor cell is not only arranged in the first trench but is also arranged in the second trench below the insulating material 33, adjacent the body regions 13, and dielectrically insulated from the body region 13, by the gate dielectric 31. Like the gate electrode 21 in the first trench, the gate electrode 21 in the second trench is connected to the gate node G.

Optionally, the gate electrode 21 in the second trench, other than the gate electrode 21 in the first trench, is connected to the source node S. In this embodiment, the gate electrode 21 in the second trench acts as a field-electrode and does not serve for controlling a conducting channel in the body region 13.

According to yet another embodiment (not shown) the gate electrode 21 of each transistor cell is only arranged in the second trench. In this case, the first trench is completely filled with the field electrode dielectric 32.

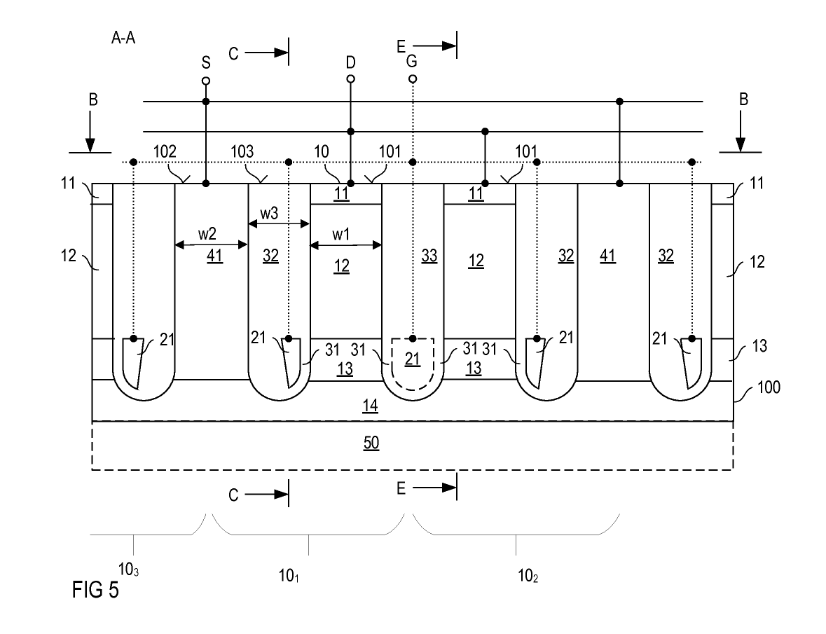

FIG. 5 shows a vertical cross sectional view of a power transistor according to another embodiment. Unlike the embodiments shown in FIGS. 1 and 3, in the power transistor shown in FIG. 5, the gate electrode 21 in the first trench is only located in those sections which are adjacent the body region 13. That is, the gate electrode 21 is only adjacent the sidewall of the first trench which faces the body region 13. This helps to reduce the gate-source capacitance. The optional gate electrode 21 in the second trench (between the two semiconductor fins with drain regions 11, drift regions 12, and body regions 13) is adjacent both sidewalls of the second trench, as both sidewalls of the second trench face the body regions of beneath the neighboring first and second transistor cells 10₁, 10₂.

FIG. 6 shows a vertical cross sectional view of a gate electrode 21 and the field electrode dielectric 32 of one transistor cell in a section plane C-C (see, FIG. 1). Referring to FIG. 6, a gate connection electrode 22 may extend from the gate electrode 21 to the surface 103 of the field electrode dielectric 32. In this surface 103 the gate connection electrode 22 may be contacted in order to be connected to the gate node G. Referring to FIGS. 2 and 4 (which each show a top view of the gate connection electrodes 22 of the individual transistor cells) the gate connection electrodes 22, in this embodiment, are insulated from the semiconductor fin and the field electrode 41 by sections of the field electrode dielectric 32.

Referring to FIGS. 2 and 4, the semiconductor fins and the field electrodes 41 may be terminated in their longitudinal directions by a further trench. This further trench may be substantially perpendicular to the trenches which accommodate the gate electrodes 21 and the field electrode dielectrics 32, 33. This further trench includes a section of the gate electrode 21 in a lower trench section and a further dielectric 34 in an upper trench section. The gate connection electrodes 22 are electrically connected to the section of the gate electrode 21 in the further trench. Referring to FIGS. 2 and 4, in which the positions of the gate electrodes 21 are illustrated in dashed lines, the gate electrodes 21 in the trenches below the field electrode dielectric 32 and/or the field electrode dielectric 33 may be electrically connected with each other through an electrode in the further trench. The gate connection electrodes 22 are connected to this electrode. Although FIGS. 2 and 4 show several gate connection electrodes 22 it should be noted that one gate connection electrode would be sufficient in this embodiment. The gate connection electrode(s) is/are connected to the gate node G (not shown in FIGS. 2 and 4).

According to another embodiment (not shown), the gate electrodes 21 extend into the further trench but are not electrically connected with each other in the further trench. In this embodiment, each of the gate electrodes 21 is connected to a gate connection electrode 22, wherein the individual gate connection electrodes are connected to the gate node G.

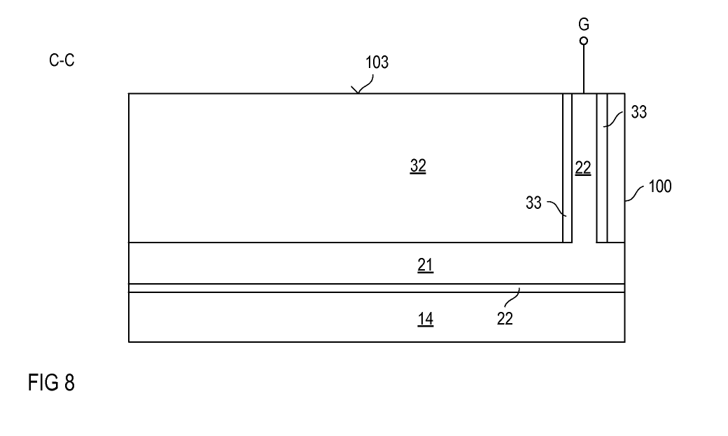

FIG. 7 shows a top view of a power transistor according to another embodiment. In this embodiment, the gate connection electrode 22 is a longitudinal electrode, and is arranged in a trench which extends substantially perpendicular to the first trenches of the individual transistor cells, and FIG. 8 shows a vertical cross sectional view of the power transistor shown in FIG. 7 in the section plane F-F shown in FIG. 7. Referring to FIGS. 7 and 8, the gate connection electrode 22 extends down to the gate electrodes 21 in the individual first trenches and is electrically or dielectrically insulated from semiconductor regions of the semiconductor fins and the source region 14, respectively, by insulation layers 33.

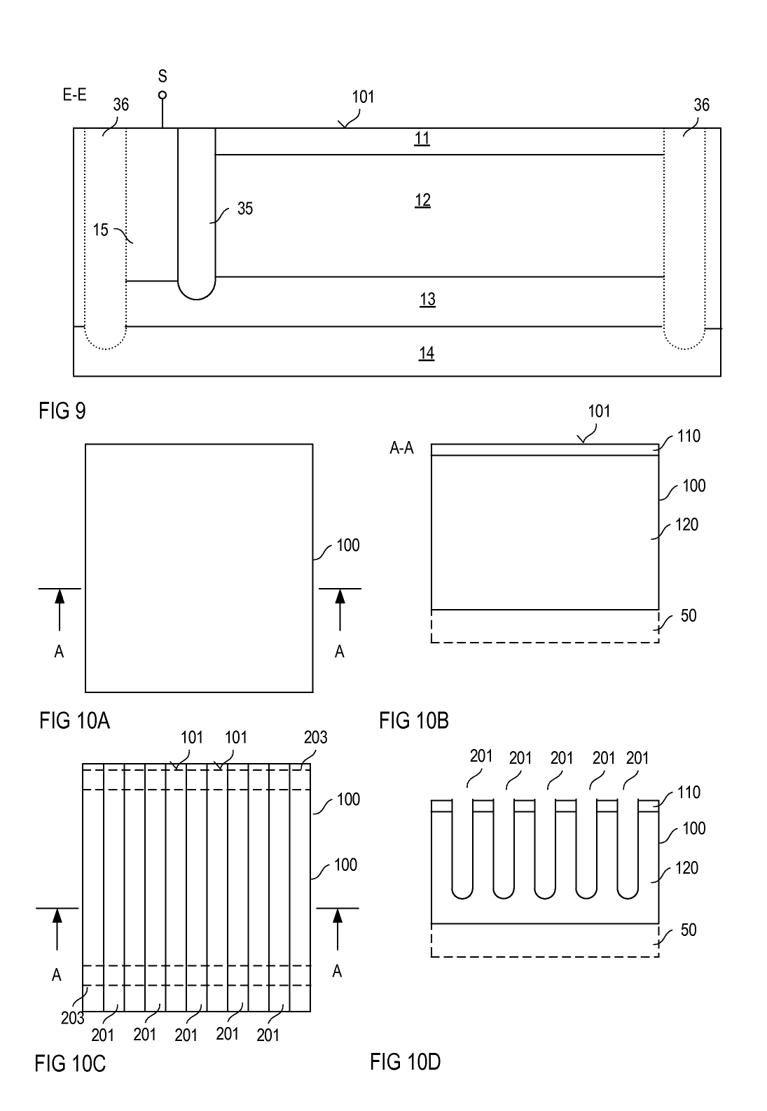

FIG. 9 shows a vertical cross sectional view (in section plane E-E shown in FIGS. 1 and 3) of a semiconductor fin of one transistor cell according to one embodiment. In this embodiment, the body region 13 is electrically connected to the source node S through a contact region 15 which extends from the surface 101 of the semiconductor fin down to the body region 13. In the longitudinal direction of the semiconductor fin, the contact region 15 is electrically or dielectrically insulated from the drain and drift regions 11, 12 by an insulation layer 35. This insulation layer is arranged in a trench which extends from the surface of the semiconductor fin down to the body region 13. According to one embodiment, the contact region 15 is located near a longitudinal end of the semiconductor fin. In the embodiment shown in FIG. 9, the longitudinal ends of the semiconductor fin are formed by trenches which extend from the surface 101 down to the source region 14 (or even beyond the source region 14) and are filled with an electrically or dielectrically insulating material 36.

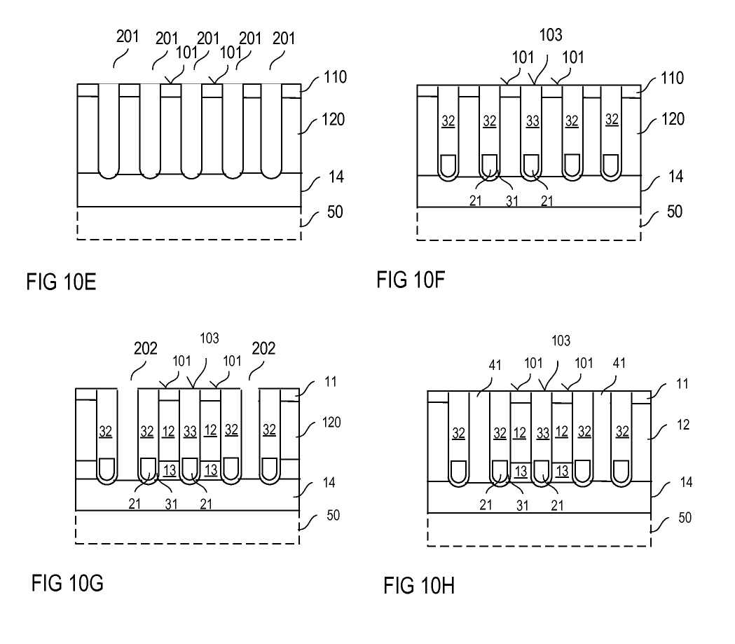

FIGS. 10A-10H show one embodiment of a method for producing a power transistor according to one of the embodiments explained hereinbefore. FIG. 10A shows a top view and FIG. 10B shows a vertical cross sectional view of the semiconductor body 100 at the beginning of the method. Referring to FIG. 10B, the semiconductor body 100 may include two semiconductor layers, a first semiconductor layer 110 forming drain regions of the transistor cells in the finished power transistor, and a second semiconductor layer 120 in which drift regions 12, body regions 13 and the source region 14 of the individual transistor cells are formed. Optionally, the second semiconductor layer 120 adjoins the carrier 50. According to one embodiment, the carrier 50 includes an electrically insulating material such as a ceramic. According to another embodiment, the carrier 50 is a semiconductor substrate. The semiconductor substrate may have the same doping type as the second semiconductor layer 120, or a doping type complementary to the doping type of the second semiconductor layer 120. When the carrier is a semiconductor substrate the first and second layers 110, 120 may be part of an epitaxial layer grown on the substrate 50. The doping concentration of the second layer 120 may correspond to a basic doping concentration of the epitaxial layer formed during the growth process. The first layer 110 is, for example, a doped layer formed by at least one of an implantation and diffusion process. According to another embodiment, the first and second layers 110, 120 are formed in the semiconductor substrate 50 by at least one of an implantation and diffusion process.

FIG. 10C shows a top view of the semiconductor body 100, and FIG. 10D shows a vertical cross sectional view of the semiconductor body 100 after process steps in which a plurality of trenches 201 is formed in the semiconductor body 100. These trenches 201 extend through the first layer 110 into the second layer 120 and may be formed using a conventional etching process, such as, for example, an anisotropic etching process.

Referring to FIG. 10E the method further includes forming the source region 14 in the second semiconductor layer 120. Forming the source region 14 may include implanting dopant atoms into the bottoms of the trenches 201 and diffusing the implanted dopant atoms in the second semiconductor layer 120. A protection layer (not shown) may cover top surfaces 101 of the semiconductor fins formed by etching the trenches in order to prevent dopant atoms from being implanted into the semiconductor fins.

According to one embodiment, the protection layer is omitted so that dopant atoms are implanted into the bottom of the trenches 201 and into the semiconductor fins close to the surface 101. Those dopant atoms implanted into the fins (after a diffusion process) form the drain region. In this embodiment, the source region 14 and the drain regions 11 are formed by the same process steps. In this case forming the first layer 110 is omitted.

According to another embodiment (not shown), the source region 14 is formed before forming the trenches 201 (that is, in the semiconductor body 100 shown in FIG. 10B) by implanting dopant atoms via the first surface 101 into the semiconductor body 100.

According to yet another embodiment, the source region 14 is formed in an epitaxy process as part of the second layer 120.

Referring to FIG. 10F, further method steps include forming the gate electrodes 21 and the gate dielectrics 31 at least in those trenches forming the first trenches in the finished power transistor. In the embodiment shown in FIG. 10F, gate electrodes 21 and gate dielectrics 31 are formed in each of the trenches 201, i.e., in those trenches forming the first trenches and the second trenches in the finished power transistor. Forming the gate electrodes 21 and the gate dielectrics 31 may include forming the gate dielectric 31 on the bottoms and at least on lower sidewall sections of the individual trenches 201. “Lower sidewall sections” of the individual trenches 201 are those sections of the individual trenches that are adjacent the body regions 13 in the finished power transistor. Forming the gate dielectrics 31 may include an oxidation process. Forming the gate electrodes 21 may include filling the trenches 201 with an electrode material in those regions adjacent the body regions 13 in the finished power transistor. This may include completely filling the trenches 201 with the electrode material, and recessing the electrode material down to adjacent the body region 13. Above the gate electrodes 21, the trenches 201 may be filled with a dielectrically insulating material. This dielectrically insulating material, optionally together with parts of the gate dielectric 31, forms the field electrode dielectrics 32 in the first trenches of the finished power transistor and the insulating material 33 in the second trenches of the finished power transistor.

Referring to FIGS. 10G and 10H, further methods steps include removing those semiconductor fins which are located between two neighboring first trenches (which are the trenches with the field electrode dielectrics 32). Removing those semiconductor fins between neighboring first trenches may include an etching process, in particular an isotropic etching process. Referring to FIG. 10H trenches 202 formed by removing semiconductor fins between first trenches are filled with an electrically conducting material so as to form the field electrodes 41.

In a depletion transistor, the body regions 13 have the same doping type as the drift region 12. In this case, the body regions 13 can be formed by the second semiconductor layer 120, so that no additional method steps are necessary in order to form the body regions 13. In an enhancement transistor, the body region 13 has a doping type complementary to the doping type of the source region 14 and the drift region 12. There are several methods to form such body region 13 some of which are explained in the following.

According to one embodiment, the source region 14, the body region 13 and the drift region 12 are formed as part of an epitaxial layer on the substrate 50. In this embodiment, the source and body regions 14, 13 have already been formed in the semiconductor body 100 before the trenches 201 are formed. The drain region 11 may be formed by implanting (and diffusing) dopant atoms, or may also be formed as part of the epitaxial layer.

According to another embodiment, the source and body regions 14, 13 are formed by implanting dopant atoms via surface 101 into the semiconductor body 100 before forming the trenches. Different implantation energies are chosen in these processes so as to implant the dopant atoms of the source region 14 deeper into the semiconductor body 100 than the dopant atoms of the body region 13.

According to yet another embodiment, the source region 14 is formed by implanting the dopant atoms into the bottom of the trenches 201 and diffusing the implanted dopant atoms. In this embodiment, the trenches 201 are formed in two steps. In a first step the trenches are etched down to the desired position of the body region 13 and dopant atoms of the body region 13 are implanted into the bottom of the trenches and diffused. In a next step, the trenches are etched down to their final depth and the dopant atoms of the source region 14 are implanted into the bottom of the trenches and diffused. According to one embodiment, only one diffusion process is used to diffuse the dopant atoms of the body region 13 and the source region 14.

According to one embodiment, referring to FIG. 10C, not only the parallel trenches 201 forming the semiconductor fins are produced in the semiconductor body 100, but two further trenches 203 (illustrated in dashed lines) are produced. Those further trenches are spaced apart in longitudinal directions of the semiconductor fins and may extend as deep into the semiconductor body 100 as the trenches 201 forming the semiconductor fins. In these further trenches 203, like in the trenches 201 a gate electrode and a gate electrode dielectric may be formed in lower trench sections. However, unlike the trenches 201, these trenches may not completely be filled with an dielectrically insulating material above the gate electrodes, but a connection electrode is formed in at least one of these trenches 201, so as to form at least one gate connection electrode 22 as shown in FIG. 6. These two trenches 203, terminate the semiconductor fins at their longitudinal ends. Depending on the width of the trench 203, the trenches may be filled completely with the insulating material 36 shown in FIG. 9. In addition one trench 203 with a shallower depth down to the body region 13 may separate a body contact region within the fin, as shown in FIG. 9. The trench with the insulating material 35 shown in FIG. 9 can also be formed parallel to one of the trenches 203 by using the etch effect, according to which the trench depth is dependent on the width of the trench.

In the description hereinbefore, directional terminology, such as “top,” “bottom,” “front,” “back,” “leading,” “trailing” etc., is used with reference to the orientation of the figures being described. Because components of embodiments can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

Although various exemplary embodiments of the invention have been disclosed, it will be apparent to those skilled in the art that various changes and modifications can be made which will achieve some of the advantages of the invention without departing from the spirit and scope of the invention. It will be obvious to those reasonably skilled in the art that other components performing the same functions may be suitably substituted. It should be mentioned that features explained with reference to a specific figure may be combined with features of other figures, even in those cases in which this has not explicitly been mentioned. Further, the methods of the invention may be achieved in either all software implementations, using the appropriate processor instructions, or in hybrid implementations that utilize a combination of hardware logic and software logic to achieve the same results. Such modifications to the inventive concept are intended to be covered by the appended claims.

Spatially relative terms such as “under,” “below,” “lower,” “over,” “upper” and the like, are used for ease of description to explain the positioning of one element relative to a second element. These terms are intended to encompass different orientations of the device in addition to different orientations than those depicted in the figures. Further, terms such as “first,” “second” and the like, are also used to describe various elements, regions, sections, etc. and are also not intended to be limiting. Like terms refer to like elements throughout the description.

As used herein, the terms “having,” “containing,” “including,” “comprising” and the like are open ended terms that indicate the presence of stated elements or features, but do not preclude additional elements or features. The articles “a,” “an” and “the” are intended to include the plural as well as the singular, unless the context clearly indicates otherwise.

With the above range of variations and applications in mind, it should be understood that the present invention is not limited by the foregoing description, nor is it limited by the accompanying drawings. Instead, the present invention is limited only by the following claims and their legal equivalents.

It is to be understood that the features of the various embodiments described herein may be combined with each other, unless specifically noted otherwise.

What is claimed is:

1. A power transistor comprising at least two transistor cells, each comprising:
a drain region, a drift region, and a body region in a semiconductor fin of a semiconductor body;
a source region adjoining the body region;
a gate electrode adjacent the body region and dielectrically insulated from the body region by a gate dielectric;
a field electrode dielectrically insulated from the drift region by a field electrode dielectric, and connected to the source region, wherein the field electrode dielectric is arranged in a first trench between the semiconductor fin and the field electrode;
wherein the at least two transistor cells comprise a first transistor cell, and a second transistor cell, and
wherein the semiconductor fin of the first transistor cell is separated from the semiconductor fin of the second transistor cell by a second trench different from the first trench.

2. The power transistor of claim 1, wherein the at least two transistor cells comprise a third transistor cell, wherein the first transistor cell and the third transistor cell have the same field electrode.

3. The power transistor of claim 1, wherein the gate electrode and the gate dielectric are arranged in the first trench.

4. The power transistor of claim 1, wherein the gate electrode and the gate dielectric are arranged in the second trench.

5. The power transistor of claim 1, wherein the at least two transistor cells are connected in parallel by having the gate electrode of each transistor cell connected to a gate node, by having the drain region of each transistor cell connected to a drain node, and by having the field electrode of each transistor cell connected to a source node.

6. The power transistor of claim 1, wherein the second trench accommodates a further gate electrode dielectrically insulated from the body regions of the first and second transistor cells by a further gate dielectric.

7. The power transistor of claim 1, wherein the body region has the same doping type as the source region.

8. The power transistor of claim 1, wherein the body region has a doping type complementary to the doping type of the source region.

9. The power transistor of claim 1, wherein the field electrode comprises a material selected from the group consisting of:
a metal;
a metal nitride;
carbon; and
a highly doped polycrystalline semiconductor material.

10. The power transistor of claim 5,
wherein each of the at least two transistor cells further comprises a body contact electrode,
wherein the body contact extends from a surface of the semiconductor fin to the body region, is electrically insulated from the drift region, is adjacent the drift region in a longitudinal direction of the semiconductor fin,
and is connected to the source node.

11. The power transistor of claim 5, further comprising:
at least one gate contact electrode connected between the gate electrodes of the at least two transistor cells and the gate node.

12. The power transistor of claim 11, wherein each transistor cell comprises a gate contact electrode.

13. The power transistor of claim 11,
wherein the at least two transistor cells have a common gate contact electrode arranged in a third trench,
wherein the third trench has a longitudinal direction which is perpendicular to longitudinal directions of the semiconductor fins.

14. The power transistor of claim 1,
wherein the semiconductor fin has a width and a length,
wherein a ratio between the length and the width is selected from one of
at least 2:1
at least 100:1,
at least 1000:1, and
at least 10000:1.

15. The power transistor of claim 1, wherein the number of the plurality of transistor cells is selected from one of
at least 100,
at least 1000, and
at least 10000.

16. The power transistor of claim 1,
wherein the source region is implemented in a buried layer, and
wherein the buried layer adjoins a carrier layer.

17. A method for producing a power transistor comprising:
forming a gate electrode, a gate electrode dielectric and a field electrode dielectric in each of a first trench adjacent a first semiconductor fin, and a second trench adjacent a second semiconductor fin;
forming an insulation layer in a third trench between the first and the second semiconductor fin;
forming a first field electrode spaced apart from the insulation layer and the first semiconductor fin and adjacent the field electrode dielectric formed in the first trench; and
forming a second field electrode spaced apart from the insulation layer and the second semiconductor fin and adjacent the field electrode dielectric formed in the second trench.

18. The method of claim 17, further comprising:
forming a gate electrode, a gate electrode dielectric and a field electrode dielectric in a fourth trench adjacent a third semiconductor fin and spaced apart from the first field electrode,
wherein the third semiconductor fin adjoins the first field electrode.

19. The method of claim 17,
wherein forming the first field electrode comprises at least partially removing a semiconductor fin adjacent the first trench, and
wherein forming the second field electrode comprises at least partially removing another semiconductor fin adjacent the second trench.

20. The method of claim 17, further comprising:
forming a buried source region after forming the trenches and before forming the gate electrode, the gate dielectric, and the field electrode dielectric.

21. The method of claim 17, further comprising:
forming a body region, a drift region and a drain region in each of the first, second, and third semiconductor fins.

22. The method of claim 21, further comprising:
forming a body contact electrode in each of the first and second semiconductor fins such that body contact electrode extends from a surface of the semiconductor fin to the body region, is electrically insulated from the drift region, and is adjacent the drift region in a longitudinal direction of each of the first, and second semiconductor fins.

23. The method of claim 17, further comprising:
forming at least one gate contact electrode connected between the gate electrodes of the at least two transistor cells and the gate node.
